(19) United States
(12) Patent Application Publication
(10) Pub. No.: US 2026/0310412 A1
(43) Pub. Date: Oct. 8, 2026

(54) Self-tracking time-based multiply and accumulate computation

(71) Applicant: ANAFLASH INC., Sunnyvale, CA (US)

(72) Inventors: Shahrzad Naraghi, San Jose, CA (US); Ankush Goel, San Jose, CA (US)

(21) Appl. No.: 19/638,716

(22) Filed: Apr. 3, 2026

Related U.S. Application Data
(60) Provisional application No. 63/783,265, filed on Apr. 4, 2025.

(51) Int. Cl. G06F 7/544

(52) U.S. Cl. CPC G06F 7/5443

(57) ABSTRACT

Disclosed are memory device, systems, and methods for performing self-tracking time-based multiply and accumulate computations. In some embodiments, the memory device comprises: a memory array comprising a plurality of memory cells; a first circuit comprising a plurality of digital-to-time converters (DTC); a second circuit comprising a plurality of time-to-digital converters (TDC); and a time reference circuit operatively coupled to both the plurality of DTCs and the plurality of TDCs, wherein the time reference circuit is configured to synchronously generate and distribute a set of common time-staggered signals to the plurality of DTCs and the plurality of TDCs.

### CROSS-REFERENCE TO RELATED APPLICATIONS

This application claims priority to and the benefit of Provisional U.S. Patent Application No. 63/783,265, filed on Apr. 4, 2025.

### TECHNICAL FIELD OF THE INVENTION

The present disclosure relates generally to the field of semiconductor integrated circuits and compute-in-memory (CIM) architectures. More specifically, the present disclosure relates to time-domain signal processing for executing multiply-and-accumulate (MAC) operations within a memory-centric computing environment.

More specifically, embodiments of the present disclosure relate to systems and methods configured to facilitate high-efficiency computation by transforming digital operands into time-domain signals via digital-to-time converters (DTC) and extracting resultant computational values via time-to-digital converters (TDC).

### BACKGROUND OF THE INVENTION

Modern signal-processing and machine-learning workloads rely heavily on vector-matrix multiplication (VMM), which is typically implemented as repeated multiply-and-accumulate (MAC) operations. In conventional von Neumann systems, weights and activations are repeatedly moved between memory and compute logic, and such data movement can dominate energy and latency as array sizes scale.

To reduce data movement, compute-in-memory (CIM) and in-array computing techniques have been proposed in which multiplication and accumulation are performed within or near a memory array (e.g., by summing currents and/or charges on a column line) and then converting the accumulated analog quantity into a digital output. However, many analog or mixed-signal CIM approaches rely on analog-to-digital conversion (ADC) at the end of each column (or each tile). ADCs and their reference generation can impose substantial area, power, and latency overhead, and practical systems often incorporate calibration and compensation procedures to manage converter offsets and analog nonidealities across channels and operating conditions.

In addition to analog-domain readout, time-domain CIM approaches have been developed to represent inputs (and/or outputs) using pulse count, pulse width, or delay, enabling time-based digitization using counters or TDCs. For example, some CIM disclosures describe representing a multi-bit input by a pulse train or a single pulse whose width is proportional to the input value, and converting a column's accumulated signal to a voltage or a time length that is digitized by “time-domain ADC” circuitry using a comparator and a counter.

Despite these developments, time-domain CIM implementations remain sensitive to timing nonidealities, because time quantization depends on delay units and sampling events whose effective time unit (e.g., inverter delay, reference period, or time resolution) can vary with process, voltage, temperature (PVT), and local mismatch. Prior time-domain CIM literature explicitly highlights that PVT variations and leakage can lead to non-uniform delay for the “same” input condition and that mitigation may require design techniques or calibration. For instance, time-domain CIM analyses distinguish global (chip-to-chip) and local (on-chip) process variations and note that, even when global variations affect all delay paths similarly, accuracy can be limited by local variations and mismatch.

Accordingly, several time-domain CIM designs include explicit calibration resources or procedures. Representative works report reserving dedicated cells or structures for calibration inside the computing macro, and other time-domain CIM demonstrations describe multilevel delay calibration to compensate delay-element mismatch and to maintain temporal resolution.

Separately, multi-column imaging and sensing readout architectures often use shared references (e.g., single-slope column ADCs that distribute a global ramp and use per-column comparators/counters) yet still employ additional techniques (e.g., digital Correlated Double Sampling, CDS, and careful distribution) to address column offsets, skew, and nonidealities. These examples illustrate that sharing a reference can help, but per-column mismatch and distribution skew can still create channel-dependent errors requiring mitigation.

In time-domain computing circuits more broadly, shared timing generation has also been used to reduce variation in the time-encoding stage. However, such sharing is typically presented as an encoder-side (time generation/selection) technique and does not necessarily establish an end-to-end constraint that the same time reference circuit be used for both input time encoding and output time digitization for MAC performed in a multi-column array.

There remains a need for in-array MAC architectures that reduce the calibration burden associated with time-base mismatch and multi-column digitization, while retaining the benefits of time-domain representation. One approach is to employ an end-to-end shared time-reference circuit that is used by input digital-to-time conversion (or pulse generation) and output time-to-digital conversion (or edge-based digitization) across a multi-column array, so that common-mode drift in the time reference is applied to both encoding and decoding and the In-Memory Computing (IMC) data path becomes self-tracking with respect to that shared reference. Such an approach can also be applied when the MAC result is formed in current/charge/voltage domain and then converted into time (e.g., by controlled discharge time) prior to digitization, thereby enabling a shared time reference to serve as a common lock point for both input and output conversions.

### SUMMARY OF INVENTION

Disclosed herein are new devices, systems, and methods to implement MAC computations (also referred to herein as MAC operations) in the time-domain using a shared timing-reference circuit that provides synchronized, time-staggered signals to both the input (DTC) and output (TDC) circuitries of the memory array.

According to the present invention, a memory device includes: a memory array including a plurality of memory cells; a first circuit including a plurality of digital-to-time converters (DTC); a second circuit including a plurality of time-to-digital converters (TDC); and a time reference circuit operatively coupled to the plurality of DTCs and the plurality of TDCs, wherein the time reference circuit is configured to synchronously generate and distribute a set of time-staggered signals to the plurality of DTCs and the plurality of TDCs.

In some aspects, the techniques described herein relate to an apparatus, wherein the memory array is configured to: perform a plurality of multiply-accumulate (MAC) operations; and output, via a corresponding bit line, an intermediate signa representing a sum of products of the MAC operations, wherein the intermediate signal includes one of: a time-domain pulse signal having a pulse width corresponding to the sum of products and an accumulated analog signal including at least one of an accumulated current or an accumulated voltage.

In some aspects, the techniques described herein relate to an apparatus, wherein each DTC may be configured to transform a digital input signal into a time-domain output pulse, wherein a duration or a phase offset of the time domain output pulse corresponds to a magnitude of the digital input signal.

In some aspects, the techniques described herein relate to an apparatus, wherein each DTC includes: a plurality of time-staggered input ports configured to receive a plurality of time-staggered versions of a reference pulse via a plurality of delay lines coupled to the time reference circuit; one or more digital input ports configured to receive a multi-bit digital code; a multiplexer configured to select one of the plurality of time-staggered versions of the reference pulse based on the multi-bit digital code; and a common output port configured to provide the selected time-staggered version of the reference pulse.

In some aspects, the techniques described herein relate to an apparatus, wherein the digital input ports are configured to receive an n-bit signal, and the multiplexer is configured to select one of 2ⁿ distinct temporal phases derived from the time reference circuit.

In some aspects, the techniques described herein relate to an apparatus, wherein the plurality of DTCs may be disposed along rows of the MAC array, and wherein a total number of DTCs is based on a number of the rows in the memory array.

In some aspects, the techniques described herein relate to an apparatus, wherein the time reference circuit includes: an input node configured to receive a reference trigger signal; a delay line including a plurality of unit delay cells arranged in series, each unit delay cell configured to impart a predetermined temporal delay to the reference trigger signal; and a plurality of output taps, each output tap coupled to a node between adjacent unit delay cells to provide the set of time-staggered signals.

In some aspects, the techniques described herein relate to an apparatus, wherein each TDC is coupled to a corresponding column of the MAC array.

In some aspects, the techniques described herein relate to an apparatus, wherein each TDC is configured to: receive the time-domain pulse signal from the plurality of memory cells via the corresponding column of the memory array, the time-domain pulse signal having a pulse width or a temporal edge position representing the sum of products of the MAC operations; and quantize the time-domain pulse signal to generate a multi-bit digital output signal by comparing a temporal characteristic of the time-domain pulse signal against at least one of the time-staggered signals distributed by the time reference circuit.

In some aspects, the techniques described herein relate to an apparatus, wherein each TDC includes: a comparator unit including at least one comparator, the comparator unit configured to generate a common pulse signal based on a comparison of the accumulated analog signal against a reference threshold; a sampling unit including a plurality of sampling elements, each sampling element having a data input coupled to an output of the comparator and a clock input coupled to one of the time-staggered signals distributed by the time reference circuit, the plurality of sampling elements configured to sample the common pulse signal to generate a thermometer-coded output representing a temporal characteristic of the common pulse signal; and an encoder operatively coupled to the plurality of sampling elements, the encoder configured to convert the thermometer code output into a multi-bit digital output.

In some aspects, the techniques described herein relate to an apparatus, wherein the comparator unit includes at least one capacitive element operatively coupled to a column of memory cells, wherein the at least one capacitive element is configured to: accumulate a charge representing an accumulated contribution of signals generated by the memory cells; and transduce said accumulated charge into a voltage value at an input of the at least one comparator.

In some aspects, the techniques described herein relate to an apparatus, wherein said comparator is coupled to the capacitive element, said comparator is configured to: sense a voltage level developed across the capacitive element, the voltage level being proportional to the result of a MAC operation; and generate a common pulse signal in response to the sensed voltage level reaching a reference voltage threshold.

In some aspects, the techniques described herein relate to an apparatus, wherein said comparator is further configured to distribute the common pulse to the plurality of sampling elements.

In some aspects, the techniques described herein relate to an apparatus, wherein the common pulse signal is configured to trigger sampling of the common pulse signal across the plurality of sampling elements.

In some aspects, the techniques described herein relate to an apparatus, wherein each sampling element includes: a first input terminal configured to receive one of the set of time-staggered signals from the time reference circuit; and a second input terminal configured to receive the common pulse from the comparator, wherein a time of the common pulse corresponds to a magnitude of the MAC results.

In some aspects, the techniques described herein relate to an apparatus, wherein each sampling element is configured to receive a respective time-delayed version of a reference signal to define a plurality of discrete sampling windows; and wherein each sampling element is configured to latch a logical state of the common pulse signal at a unique sampling time;

In some aspects, the techniques described herein relate to an apparatus, wherein the encoder includes: an input interface configured to receive parallel signals from the plurality of sampling elements; a transition detection circuitry configured to identify a transition bit position between a first logic state and a second logic state; and an encoding logic circuitry configured to convert the identified transition bit position into a n-bit binary number,

In some aspects, the techniques described herein relate to an apparatus, wherein the n-bit digital representation corresponds to a quantized timing position of a common pulse signal relative to a reference signal.

In some aspects, the techniques described herein relate to a method of performing a time-domain multiply-and-accumulate (MAC) operation, wherein the method including: generating and distributing, by a time reference circuit, a set of time-staggered signals to a plurality of digital-to-time converters (DTC) and a plurality of time-to-digital converters (TDC); transforming, by the plurality of DTCs, a plurality of digital input signals into time-domain pulses, wherein a temporal characteristic of each time-domain pulse is determined by selecting one of the time-staggered signals based on a multi-bit digital code; performing, via a memory array, a plurality of MAC operations by applying the time-domain pulses to a plurality of memory cells; generating, via the memory array, a plurality of intermediate signals, wherein each intermediate signal represents a sum of products of the MAC operations; and wherein each intermediate signal includes one of a time-domain pulse signal and an accumulated analog signal; and quantizing, by the plurality of TDCs, the intermediate signal to generate a multi-bit digital output signal by comparing a temporal characteristic of the intermediate signal against at least one of the time-staggered signals provided by the time reference circuit, wherein the multi-bit digital output represents a sum of respective products generated by the plurality of circuits.

In some aspects, the techniques described herein relate to a system for performing time-domain multiply-and-accumulate (MAC) computations, the system including: a time reference circuit configured to generate a plurality of time-staggered reference signals; a plurality of digital-to-time converters (DTC), each configured to receive a digital input and select one of the time-staggered reference signals received from the time reference circuit to generate a time-domain input pulse signal; a memory array including a plurality of memory cells arranged in rows and columns, the memory cells configured to perform multiply-and-accumulate (MAC) operations using the time-domain input pulse signals and to output an intermediate signal; and a plurality of time-to-digital converters (TDC), each coupled to a column of the memory array and the time reference circuit, the plurality of TDCs configured to: sample the intermediate signal against the plurality of time-staggered reference signals to identify a temporal transition; and encode the temporal transition into a digitized value representing a sum of respective products generated by the plurality of memory cells.

### BRIEF DESCRIPTION OF THE DRAWINGS

The accompanying drawings are included to provide a further understanding of the invention and are incorporated in and constitute a part of this specification. The drawings illustrate various embodiments of the invention and, together with the description, serve to explain the principles of the invention. These drawings are provided for exemplary purposes only and are not intended to be limiting.

FIG. 1 is a block diagram of a conventional system comprising a digital-to-time converter (DTC) and a time-to-digital converter (TDC).

FIG. 2 is a conceptual block diagram employing a shared time reference for self-tracking time-domain signal conversion in accordance with one or more embodiments.

FIG. 3 is a conceptual block diagram of a multiply-and-accumulate (MAC) computation path utilizing a shared time reference.

FIG. 4 is a high-level circuit diagram of an array configured to perform MAC operations in which column outputs are represented as time-domain pulses using a shared time reference circuit.

FIG. 5 is a schematic view of an alternative array architecture configured to perform MAC operations in which column outputs are represented as analog signal along a column bitline using a shared time reference circuit.

FIGS. 6A, 6B, and 6C are schematic diagrams illustrating exemplary structures and operational phases of DTC circuits configured with a shared time reference.

FIGS. 7A, 7B, and 7C are schematic diagrams illustrating exemplary structures and operational phases of TDC circuits configured to digitize timing events derived from calculated signals using a shared time reference.

### DETAILED DESCRIPTION OF THE INVENTION

In one or more embodiments, the present disclosure relates to an integrated circuit comprising a shared timing-reference circuitry operatively coupled to a plurality of converters. The shared timing-reference circuitry is configured to synchronize time-encoding and time-digitization operations across a plurality of array columns and rows, thereby maintaining computational linearity and providing resilience against Process, Voltage, and Temperature (PVT) variations.

In one embodiment, an integrated circuit comprises a memory array comprising a plurality of memory cells, wherein the memory array is configured to generate a plurality of calculated pulse signals. Each memory cell of the plurality of memory cells is configured to receive a first time-domain pulse as a primary input and, in response thereto, generate a second time-domain pulse signal as an output.

The output time-domain pulse signal represents a product of a time-domain multiply-and-accumulate (MAC) operation. This operation is performed in response to time-domain input pulses characterized by a pulse width that is substantially proportional to a digital input value. Architectural details and configurations of the integrated circuit, consistent with the present disclosure, are further described in U.S. Pat. No. 12,373,169, which is assigned to ANAFLASH Inc., the disclosure of which is hereby incorporated by reference in its entirety for all purposes.

In the following detailed description of the invention, reference is made to the accompanying drawings which form a part hereof and illustrate embodiments of the invention. In the drawings, like numerals refer to like elements throughout. The illustrated embodiments are examples and are not meant to be limiting; various modifications and equivalent arrangements will be apparent to those skilled in the art. It will be understood that terms such as “on,” “connected to,” or “coupled to” include the possibility of intervening elements or layers. The terms “first,” “second,” etc. are used only to distinguish elements and do not imply any order.

The terminology used herein is to describe particular embodiments only and is not intended to be limiting of the invention. As used herein, the singular forms “a”, “an”, and “the” are intended to include the plural forms as well, unless the context indicates otherwise. It will be further understood that the term “comprising” or “comprises,” when used in this specification, specifies the presence of stated features, integers, steps, operations, elements, and/or components, but does not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein. The description that follows is intended to illustrate the principles of the invention and not to limit the scope of the invention as set forth in the claims.

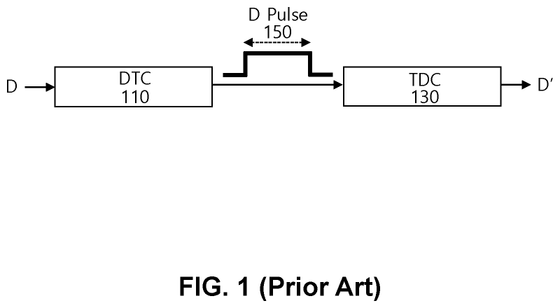

FIG. 1 illustrates a conventional asynchronous timing architecture known in the art. As depicted, a digital-to-time converter (DTC) 110 and a time-to-digital converter (TDC) 130 are configured with independent, localized internal time references. In an exemplary operation, a digital input (D)—for instance, a 4-bit value of 0110 (decimal 6)—is converted by the DTC 110 into a D pulse 150 having a duration defined by a first reference clock. If the first reference clock exhibits a first period (e.g., T1), the pulse 150 has a temporal duration of 6×T1.

However, in such conventional architectures, an output-side reference clock associated with the TDC 130 may deviate from the first reference clock due to Process, Voltage, and Temperature (PVT) variations. This results in a second, disparate clock period (T2). For purposes of illustration, if T2 is shorter than T1 (e.g., a 0.9 ratio relative to the nominal period), the TDC 130 will perform a sampling operation over 6.0×T1 the interval that yields approximately 6.67 clock cycles. The mechanism of this error is as follows:

Since time is measured in “ticks,” any variation in the length of those ticks changes the perceived value:

1. Input Side (DTC): The Digital-to-Time Converter (DTC) acts as a pulse generator. If the input D=6 and the clock period T_{ref1}=1.0 sec, the formula for the pulse width Δt is:

$$Δ t = D \times {T}_{ref 1} = 6 \times 1. s = 6. s$$

2. Output Side (TDC): The Time-to-Digital Converter (TDC) measures that 6.0-second pulse using its own clock, T_{ref2}=0.9 s. The output code D′ is calculated by seeing how many times its clock fits into the pulse:

$${D}^{′} = \frac{Δ t}{{T}_{ref 2}} = \frac{6. s}{0.9 s} \approx 6.67$$

3. Quantization: Since digital counters generally deal in integers, the TDC rounds or “counts” up to the next tick, resulting in D′=7. Consequently, the TDC 130 registers a digital count of 7, interpreting the output as decimal 7.

As a result of this timing mismatch, the output code D′ (0111₂) fails to maintain fidelity with the original input D (0110₂). While this example utilizes specific bit widths and encoding, it serves to illustrate a fundamental systemic vulnerability: when the DTC 110 and TDC 130 rely on unsynchronized or independent timing generators-such as disparate counters, delay lines, or oscillators-PVT fluctuations introduce computational non-linearity. Without complex, area-intensive calibration circuitry, such conventional asynchronous architectures cannot ensure that the encoded input value and the decoded output value remain congruent without additional calibration.

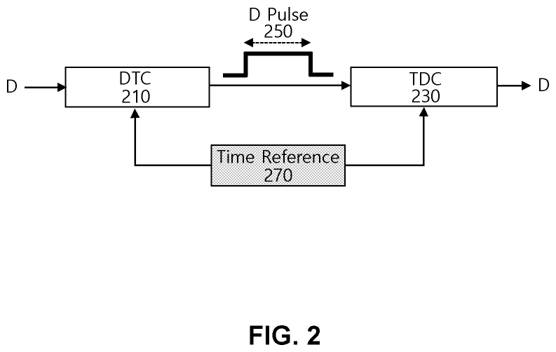

FIG. 2 illustrates a system architecture for time-domain signal processing in accordance with some embodiments. In this architecture, a Time Reference 270 is disposed external to, and operatively coupled with, both a digital-to-time converter (DTC 210) and a time-to-digital converter (TDC 230).

Unlike asynchronous designs where timing references are localized and independent, the DTC 210 and TDC 230 of the present disclosure are slaved to a common timing base provided by the centralized timing reference circuit 270. The timing reference circuit 270 may comprise timing generation means, including, but not limited to, a digital counter, a tapped delay line, a voltage-controlled oscillator (VCO), or a delay-locked loop (DLL), configured to generate and distribute a common-mode reference signal.

By utilizing a shared reference for both signal generation (encoding) and signal measurement (decoding), the system is rendered intrinsically self-tracking. As used herein, “self-tracking” refers to an operational state in which temporal variations or fluctuations within the timing reference circuit 270 are uniformly reflected in both the DTC 210 and the TDC 230. Consequently, temporal deviations induced by Process, Voltage, and Temperature (PVT) variations are substantially cancelled, neutralized, or otherwise mitigated via common-mode rejection, allowing the generated and measured signals to track each other without requiring secondary calibration.

FIG. 2 further illustrates the inherent process, voltage, and temperature (PVT) robustness of the presently disclosed architecture. In an exemplary embodiment, the numerical fidelity of the data path is maintained even when the shared timing reference 270 deviates from a nominal frequency. For instance, if the shared timing reference 270 exhibits a drifted period (Tref), the DTC 210 generates a D pulse 250 having a temporal duration defined as a multiple (N) of said period (e.g., N×Tref). Because the TDC 230 is referenced to the identical clock period (Tref), the TDC 230 samples the D pulse 250 using the same time base. In a specific functional example:
If N=6 and T_{REF} drifts to 1.1 μs, the DTC 210 generates a pulse of 6.6 μs.
The TDC 230, utilizing the same 1.1 us reference, identifies exactly six periods within the pulse.

Because the TDC 230 is referenced to the same clock period (Tref), it samples the pulse 250 using an identical time base, thereby recovering the original integer count (N=6). Because the same time reference 270 is used for both time generation and time measurement, first-order variations in the timing reference are inherently cancelled. Consequently, the output value tracks the input value even when the absolute timing characteristics of the reference change. This shared-reference architecture therefore enables self-tracking operation without requiring separate calibration between the DTC 210 and the TDC 230. The numerical example above is provided for illustration. Other encoding schemes, bit widths, and timing implementations may similarly benefit from the shared-reference configuration described herein.

The comparative architectures of FIGS. 1 and 2 show a fundamental distinction between systems comprising asynchronous, locally-embedded timing references and those employing a centralized, common-mode timing architecture.

In the conventional embodiment of FIG. 1, the timing reference is integrated as an inseparable sub-component within the respective DTC and TDC functional circuitries. By failing to treat the timing reference as a discrete and separable architectural element, this configuration renders the signal path susceptible to uncorrelated timing drift. Consequently, independent fluctuations in the respective time-bases—whether induced by process, voltage, or temperature (PVT)—introduce temporal non-linearities between the encoding and decoding stages, thereby compromising the numerical integrity of the data.

In contrast, the configuration in FIG. 2 separates the timing reference from the individual conversion circuitries and allows the same reference to be shared between the DTC and the TDC. This arrangement and configuration enable the time-domain signal generation and the corresponding measurement to track the same timing unit, thereby mitigating first-order variations in the reference and reducing the need for calibration between converters.

While FIGS. 1 and 2 illustrate the principle of shared time-reference operation in the context of signal conversion, the same concept is applied to computational architectures in which data is represented and processed in the time domain. The following figures describe example embodiments in which time-domain signals are used within a multiply-and-accumulate (MAC) computation path, where a shared time reference enables self-tracking behavior between input encoding and output digitization.

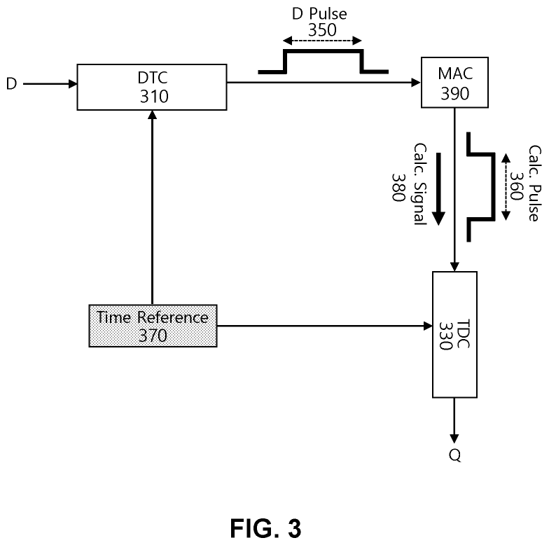

FIG. 3 shows a schematic representation of a multiply-and-accumulate (MAC) computation path utilizing a shared time reference, in accordance with an embodiment of the present disclosure. As shown, a digital-to-time converter (DTC) 310 is configured to receive a multi-bit digital input D. The DTC 310 is operatively coupled to a common time reference 370 and is configured to generate a first time-domain signal, illustrated as a digital input pulse (D-pulse) 350, having a pulse width proportional to the value of the digital input D.

The D-pulse 350 is provided to a MAC element 390, which may comprise a memory cell configured to store a programmable weight. The calculated signal may be manifested in various signal domains depending on the specific architectural implementation.

It should be noted that, in some embodiments, while the MAC element 390 is configured to receive the time-domain pulse 350 as a primary input, the internal circuit architecture of the memory cells within the MAC element 390 can be physically varied depending on whether the output is analog current/voltage, such as Calc. Signal 380, or a shifted/modulated pulse, such as Calc. Pulse 360.

In one embodiment, the MAC element 390 is configured to receive a time-domain pulse 350 as input and produce a time-domain pulse signal (i.e., Calc. Pulse 360), as an output. In this configuration, the memory cell functions as a programmable delay element, wherein the memory cell physically delays or stretches a signal based on a stored weight. Specifically, the memory cell is configured to modulate the propagation delay of an input pulse such that a high stored weight results in a first propagation delay, while a low stored weight results in a second, distinct propagation delay.

The resulting output remains a digital-swing pulse characterized as a time-shifted representation of the input. In this embodiment, multiplication and addition operations are performed by chaining a plurality of said delays. Consequently, the MAC operation of the MAC element 390 is implemented via pulse propagation or pulse accumulation along a conductive column, such that a time-domain output signal is generated substantially directly from said propagation or accumulation. The structural and operational specifications of the MAC element 390—which is configured to receive a time-domain pulse 350 as input and produce a calculated pulse signal 360 as an output—are described in U.S. Pat. No. 12,373,169 to ANAFLASH Inc., which is assigned to the assignee of the present invention and is hereby incorporated by reference in its entirety.

In alternative embodiments, the MAC element 390 is configured to receive a time-domain pulse 350 as input and produce an analog signal as output, such as Calc. Signal 380. The analog output signal may comprise a current, an electrical charge, or a voltage level corresponding to a multiply-and-accumulate result.

In this configuration, the time-domain pulse 350 serves as a temporal control signal that regulates the quantity of analog charge transferred to a shared bitline. Accordingly, the MAC element 390 is configured to execute MAC operations via the accumulation of column current or charge upon said shared bitline.

In an exemplary embodiment, during a first logic state (e.g., a high state) of the D-pulse 350, the memory cell is configured to source an output current. The output current comprises a magnitude or duration proportional to the stored programmable weight. In this configuration, a total accumulated charge—or a corresponding voltage level across a storage capacitor—is generated that is representative of the product of the digital input (D) and the stored programmable weight.

In embodiments where current or charge accumulation is employed, the accumulated analog quantity may be provided to an output digitization stage, where the analog quantity is stored and compared to generate a timing event for subsequent time-domain digitization. The timing of the generated signal is substantially proportional to the MAC result (e.g., D×weight). A time-to-digital converter (TDC) 330, also referencing the shared time reference 370, is configured to measure the pulse width of the Calc. Pulse 360. By utilizing the shared time reference 370, the TDC 330 generates a digital output Q proportional to the product of the digital input D and the weight. This shared-reference architecture facilitates the accurate capture of time-domain MAC results and may mitigate the need for per-column calibration between the DTC 310 and the TDC 330.

While FIG. 3 illustrates a MAC computation path comprising a single input, a single MAC element, and a single output digitization stage, it is understood that the shared-reference architecture may be scaled or otherwise replicated. In various embodiments, the disclosed operations are performed in parallel across a plurality of inputs and a plurality of memory elements arranged, for example, in an array structure.

Accordingly, the shared-reference time-domain processing described herein may be extended to architectures comprising a plurality of input signals, a plurality of MAC elements, and a plurality of output digitization paths operating in parallel or in a distributed manner. In such configurations, a plurality of digital inputs may be converted into a corresponding plurality of time-domain pulses via a plurality of DTCs (e.g., DTC 310) that share a common time reference (e.g., shared time reference 370). Similarly, the resulting MAC outputs from a plurality of columns or cells may be digitized by a plurality of corresponding TDCs (e.g., TDC 330) also referencing the common time reference. Such a parallelized configuration facilitates high-throughput MAC operations while maintaining the calibration-free advantages of the shared-reference scheme across the array.

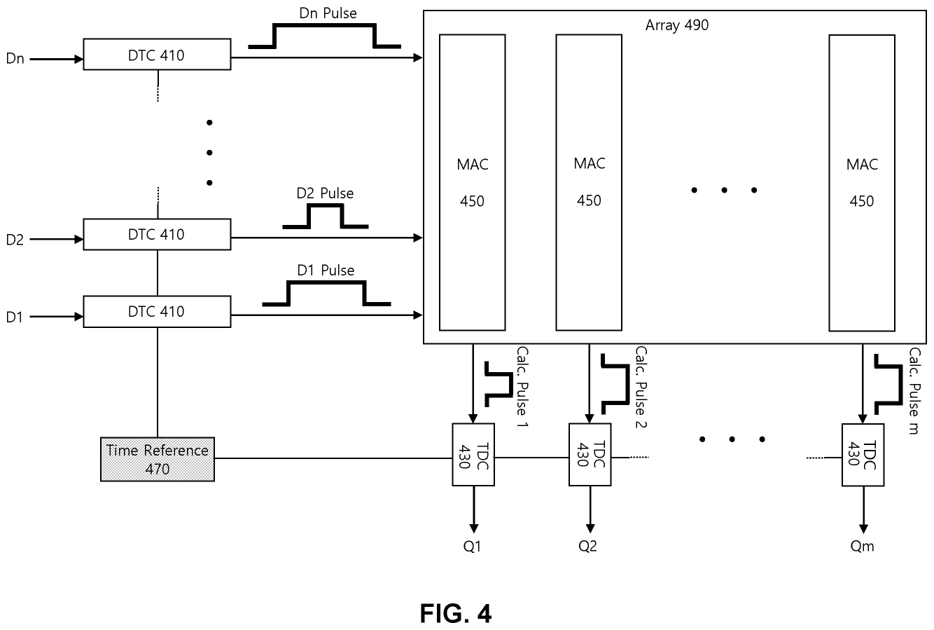

FIG. 4 illustrates a schematic view of a memory array architecture configured to implement the time-domain MAC computation previously described with respect to FIG. 3. In this embodiment, the architecture comprises a plurality of inputs, a plurality of MAC elements 450, and a plurality of output digitization circuits.

As illustrated, a plurality of digital inputs (e.g., D₁, D₂, . . . , Dₙ) are applied to a corresponding plurality of digital-to-time converter (DTC) circuits 410. Each DTC 410 is configured to convert its respective digital input into a time-domain pulse signal (e.g., D₁ Pulse, D₂ Pulse, . . . , Dₙ Pulse) having a duration or pulse width corresponding to the value of the respective digital input. The generated time-domain pulse signals are applied to corresponding rows or input lines of a MAC array 490. The MAC array 490 comprises a plurality of MAC elements 450 arranged across a plurality of columns. In various embodiments, the MAC array 490 may comprise a memory array, a pixel array, or a similar computational structure wherein MAC operations are performed within each column.

Within the MAC array 490, each column is configured to perform a time-domain multiply-and-accumulate operation based at least in part on the received time-domain pulse signals and one or more weights stored within the MAC elements 450 of the respective column. Responsive to the MAC computation within a column, a time-domain signal representing a computed result is generated. In the illustrated embodiment, the computed result for each column is directly represented as a time-domain pulse signal (e.g., Calc. Pulse₁, Calc. Pulse₂, . . . , Calc. Pulse m), the duration of which is substantially proportional to an accumulated contribution of the input pulses and the stored weights associated with that column.

Each column output is provided to a corresponding time-to-digital converter (TDC) 430 of a plurality of TDCs, which is configured to convert a respective calculated pulse into a digital output value (e.g., Q1, Q2, . . . , Qm). In this embodiment, the calculated pulse is directly supplied to the TDC 430 without intermediate conversion circuitry. The TDC 430 is configured to operate as a functional counterpart to a digital-to-time converter (DTC) 410 by determining a temporal duration of the calculated pulse relative to the shared time reference 470. Based on this temporal time determination, the TDC 430 generates a corresponding digital output value. A shared time reference circuit 470 is operatively coupled across the MAC array and is shared by both the plurality of DTC circuits 410 and the plurality of TDC circuits 430.

A single time reference circuit 470 may be shared via a common timing distribution network and may be implemented using, for example, a common counter, a delay line, an oscillator, or another suitable timing reference generator. By sharing the time reference circuit 470 to both the input pulse generation stage and the output pulse measurement stage, the architecture ensures that the time-domain encoding of the inputs and the digitization of the MAC outputs track a common timing basis across the MAC array.

Consequently, variations in the reference timing-such as those resulting from process, voltage, or temperature (PVT) fluctuations-affect both the DTC 410 and TDC 430 operations in a substantially similar manner. This shared-reference architecture facilitates self-tracking behavior across multiple MAC columns and provides at least a first-order cancellation of timing variations along the encode-compute-digitize signal path. This configuration may further reduce or eliminate the need for per-column calibration, thereby improving computational efficiency and accuracy.

The aforementioned shared-reference architecture is particularly advantageous in large-scale array configurations, wherein column-to-column timing mismatch, local delay variations, or digitization skew may otherwise introduce significant computational errors. By operatively sharing the time reference 470 to both the plurality of input encoding circuits (e.g., DTCs 410) and the plurality of output digitization circuits (e.g., TDCs 430) across the MAC array, timing mismatches between discrete columns are substantially mitigated.

Accordingly, the resulting digital outputs (Q1, Q2, . . . , Qm) represent values that are substantially proportional to the corresponding MAC results produced in their respective columns. This proportionality is maintained even in instances where the absolute timing characteristics of the shared time reference 470 fluctuate due to process, voltage, or temperature (PVT) variations.

In this manner, the shared time reference 470 facilitates a self-tracking operational mode between the input encoding stage and the output digitization stage across a plurality of MAC columns. This self-tracking behavior reduces or eliminates inter-column timing mismatch and minimizes calibration requirements (e.g., per-column offset or gain trimming) within large-scale time-domain computing arrays, thereby enhancing both the scalability and the computational precision of the system.

In conventional time-domain processing architectures, the timing references utilized for signal generation and signal measurement are typically local to, or embedded within, their respective converter circuits and operate independently of one another. Consequently, variations in process, voltage, or temperature (PVT), as well as local circuit mismatches, may induce timing discrepancies between time-domain encoding and subsequent digitization. Such discrepancies are particularly pronounced in large-scale, multi-column computing arrays.

In contrast, the embodiment of the present invention disclosed herein decouples the timing reference from the individual conversion circuitries and operatively distributes a common time reference across both the input encoding circuits (e.g., DTCs) and the output digitization circuits (e.g., TDCs). By utilizing a shared timing reference for both the generation of input time-domain signals and the measurement of resultant computational outputs, the system facilitates a self-tracking operational mode.

Timing variations affecting the shared timing reference influence both encoding and digitization operations in a substantially similar manner, thereby enabling at least a first-order cancellation of timing variations along the encode-compute-digitize signal path. This shared-reference architecture facilitates a substantial reduction in inter-column timing mismatch and mitigates or eliminates the requirement for per-column calibration in large-scale time-domain computing arrays.

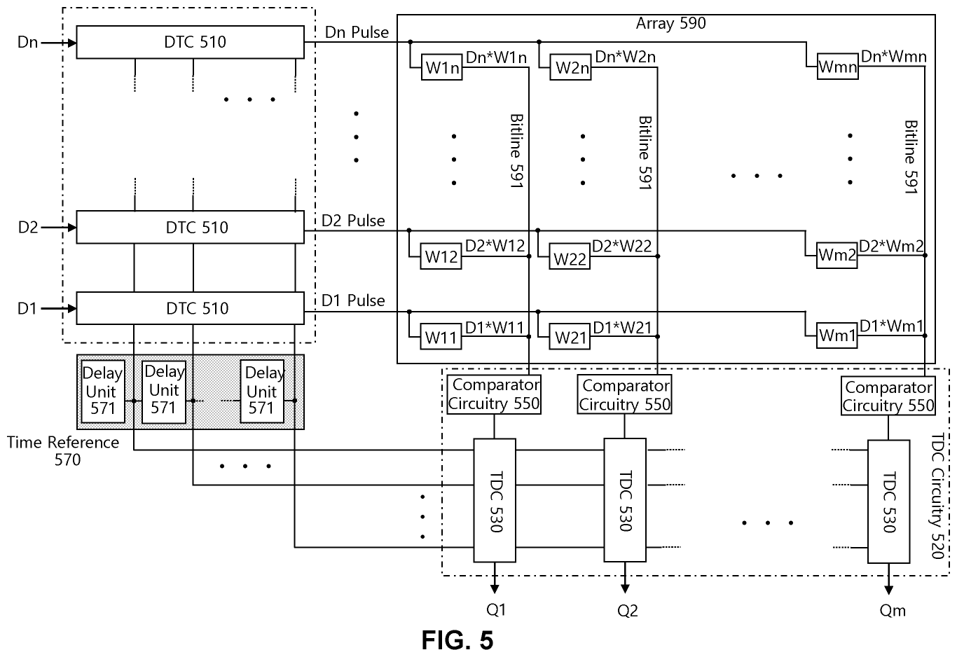

FIG. 5 illustrates an example of an array architecture configured to perform time-domain multiply-and-accumulate (MAC) computation using a charge or current accumulation mechanism. This embodiment is a different way of building the system shown in FIG. 4. While the embodiment of in FIG. 4 shows the pulse-based architecture, the present embodiment uses electrical accumulation to reach the same final result. In particular, FIG. 5 provides an expanded view of the internal operational logic and structural interconnections of the MAC array.

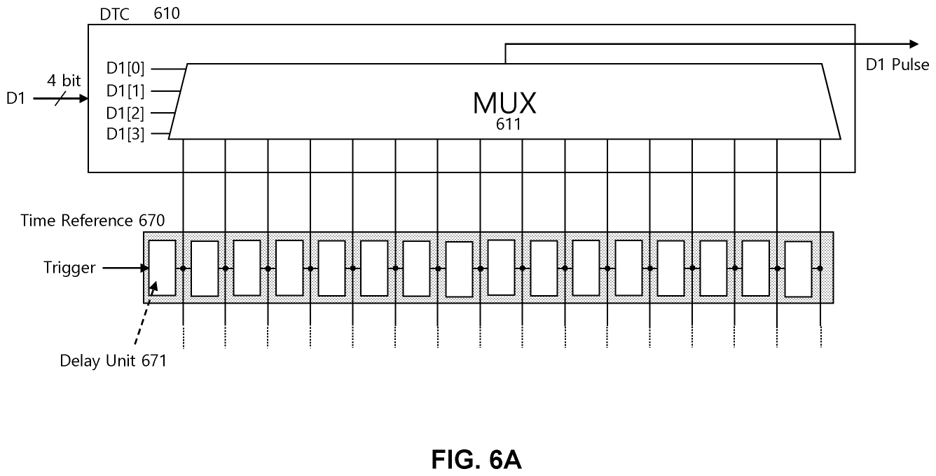

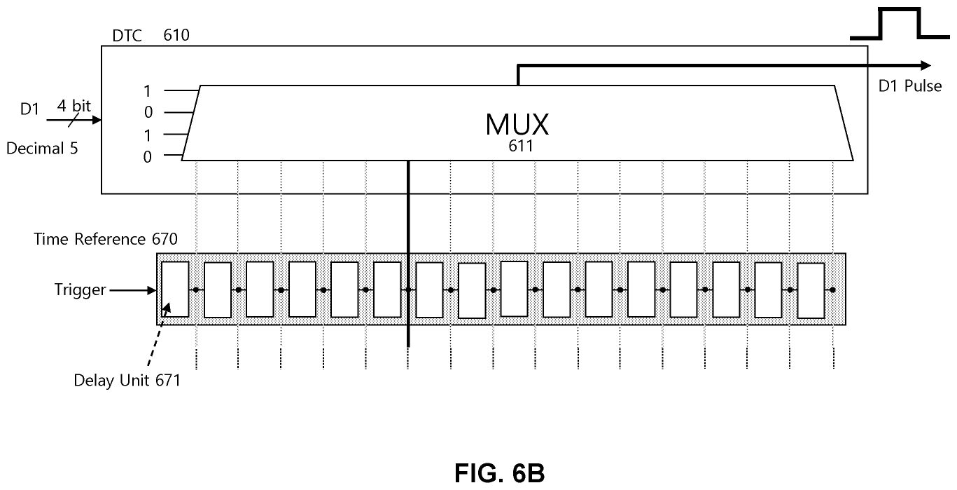

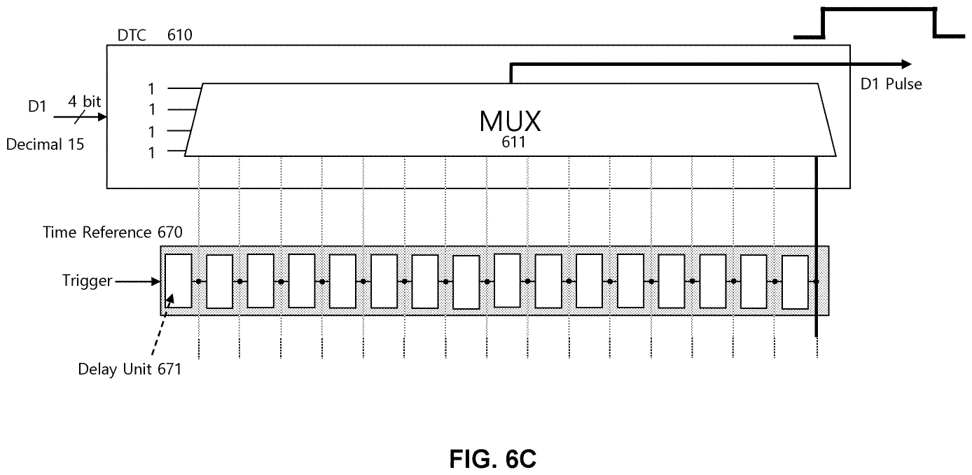

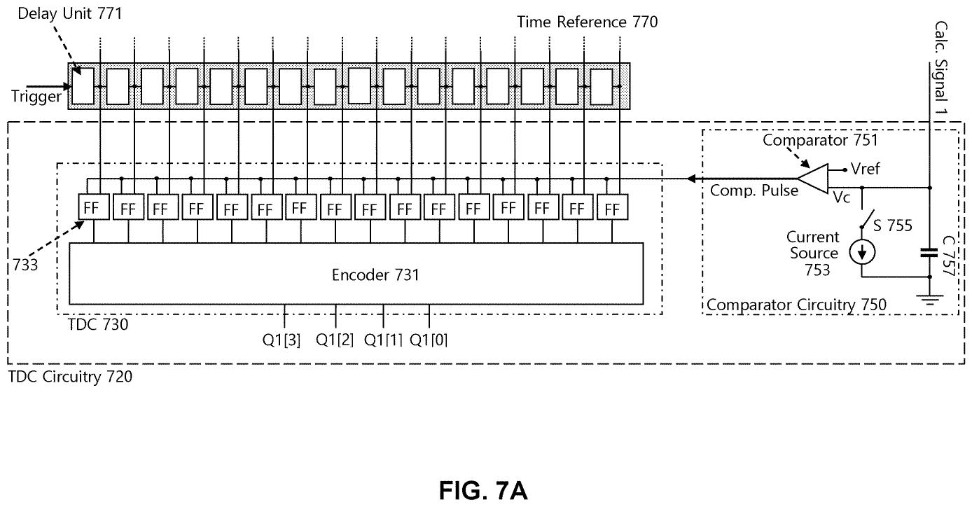

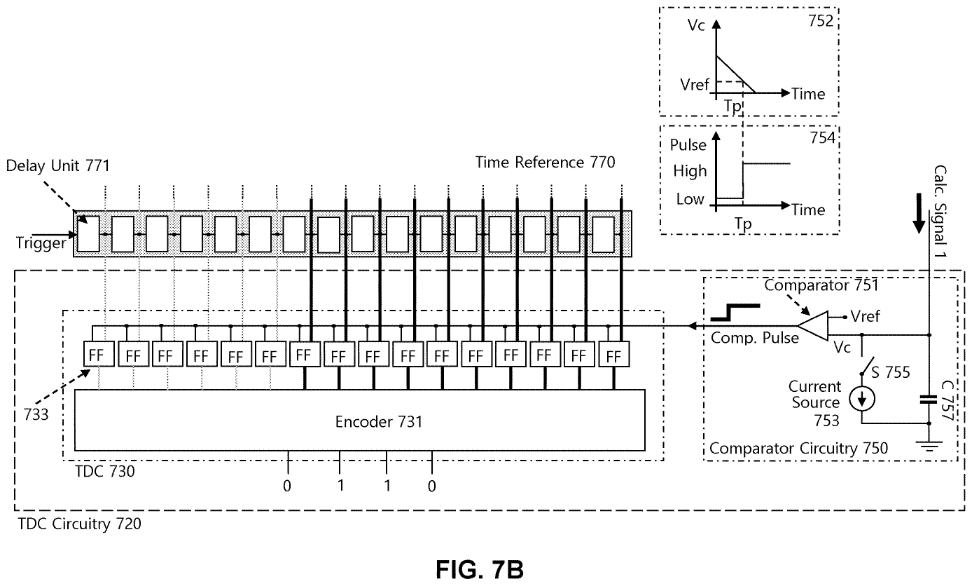

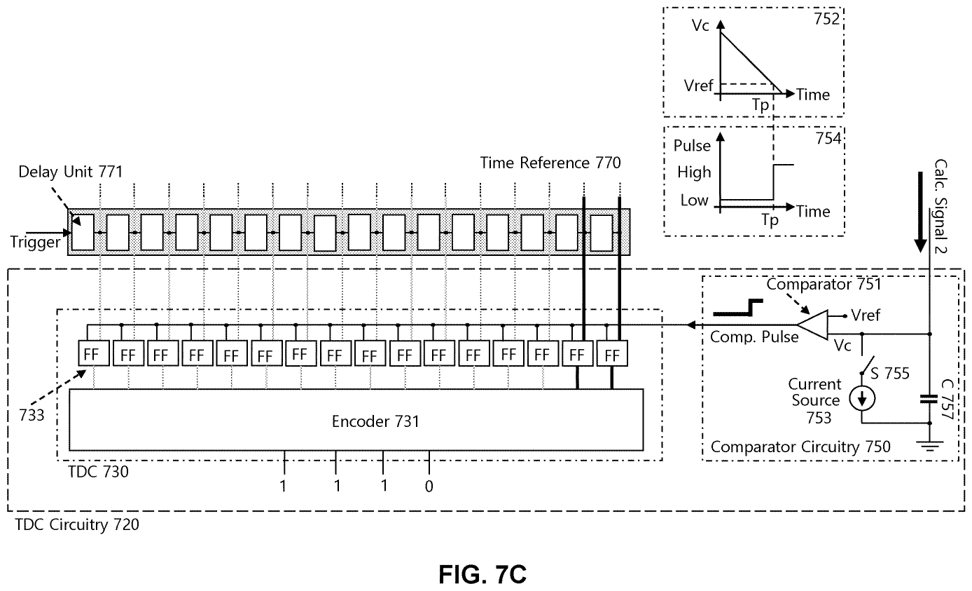

While FIG. 5 focuses on the array-level implementation, it is understood that the detailed circuit-level implementations of the input conversion circuitry (e.g., the DTCs) and the output digitization circuitry (e.g., the TDCs) are described in further detail with respect to subsequent figures (e.g., FIGS. 6A-6C and FIGS. 7A-7C, respectively). The components illustrated in FIG. 5 are intended to be exemplary, and the illustrated configurations may be modified or optimized without departing from the scope of the present disclosure.

Referring to FIG. 5, a plurality of digital inputs (e.g., e.g., D1, D2, . . . , Dn) are provided to a corresponding plurality of digital-to-time converter (DTC) circuits 510. Each DTC 510 is configured to convert a respective digital input value into a time-domain pulse signal having a duration representative of the magnitude of said digital input value. The generated time-domain pulse signals (e.g., D1 Pulse, D2 Pulse, . . . , Dn Pulse) are applied to corresponding rows of a MAC array 590 and are configured to propagate across the row structures of the MAC array 590.

The MAC array 590 comprises a plurality of columns, wherein each column is configured to store a plurality of weights corresponding to the plurality of digital inputs. In one or more embodiments, the stored weights are represented by memory elements or other programmable resistive or capacitive elements disposed at the intersections of the rows and the columns. Within the MAC array 590, each time-domain pulse signal is configured to modulate or otherwise activate a corresponding memory element to generate a weighted time-domain signal. This weighted signal represents a product of the digital input value and the stored weight associated with the respective cell at said intersection.

By way of example, a first time-domain pulse signal (e.g., D₂ Pulse) corresponding to a digital input is configured to propagate along a row structure associated with said digital input D₂. When the D₂ Pulse is received at a computational cell (e.g., a memory cell) storing a weight W₁₂ within a first column of the MAC array 590, the activation of the computational cell by the pulse generates a weighted time-domain signal. This weighted time-domain signal is representative of the product of the digital input D2 and the stored weight W₁₂ (i.e., D2×W₁₂).

Similarly, a plurality of time-domain pulse signals corresponding to other digital inputs are configured to activate respective computational cells within the same column to produce a plurality of corresponding weighted signals (e.g., D1×W11, D3×W13, . . . , and Dn×W1n.). Each such interaction is governed by the temporal duration of the respective input pulse and the programmed state of the weight-storing element, such that the resulting weighted signals are provided for subsequent accumulation within the column.

The plurality of weighted time-domain signals generated within the computational cells of a given column are operatively coupled to, and aggregated along, a corresponding column bitline 591. In this manner, the weighted signals produced by the computational cells of said column are configured to accumulate along the column bitline 591 to generate a resultant analog signal. This resultant signal is representative of the multiply-and-accumulate (MAC) result for that specific column.

For example, within a first column of the MAC array 590, the weighted signals corresponding to the products of the digital inputs and the stored weights (e.g., D1×W11, D2×W12, . . . , and Dn×W1n) are summed or otherwise integrated along the first column bitline 591. This accumulation forms a combined signal representing the aggregate contribution of the plurality of digital inputs and the plurality of stored weights associated with that column. The bitline 591 thereby functions as a summing node, facilitating the transition from individual cell products to a column-wide MAC result.

The accumulated signal present on each column bitline 591 constitutes a resultant analog signal (e.g., a voltage or charge profile) representative of the multiply-and-accumulate (MAC) result for that respective column. Unlike the pulse-based embodiment of FIG. 4, the output of the bitline in this embodiment is not directly represented as a pulse signal. This resultant signal is provided to an output digitization stage, illustrated as a time-to-digital converter (TDC) circuitry 520. Because the resultant signal is represented as an analog quantity rather than a pulse, a conversion stage is required to determine a timing event corresponding to the magnitude of the accumulated signal. Accordingly, the TDC circuitry 520 includes a comparator circuitry 550 configured to generate a pulse signal indicating a timing at which the accumulated signal reaches a reference level.

In one or more embodiments, the TDC circuitry 520 comprises a comparator circuitry 550 configured to compare the resultant signal against a reference level (e.g., a reference voltage, Vref (not shown)). The comparator circuitry 550 is configured to generate a compared pulse signal (e.g., “Comp. Pulse” (not shown)) indicating a transitional timing at which the accumulated signal traverses the reference level.

The compared pulse signal is subsequently provided to a time-to-digital converter (TDC) 530. The TDC 530 is configured to quantize the timing of said compared pulse signal into a digital output value. By utilizing the shared time reference (e.g., 470/370) previously described, the TDC 530 generates a plurality of digital outputs (e.g., Q1, Q2, . . . , Qm) that are substantially proportional to the MAC results of the respective columns. This conversion process effectively translates the analog accumulation on the bitline into a high-precision digital representation while maintaining the self-tracking benefits of the common timing basis.

As previously described with respect to FIG. 4, a time reference 570 is operatively distributed to both the plurality of DTC circuits 510 and the plurality of TDC circuits 530. In one or more embodiments, the shared time reference 570 comprises a plurality of delay units 571 configured to generate reference timing signals for time-domain encoding and subsequent measurement.

The quantity of delay units 571 may be functionally related to the bit-resolution of the digital input and output data. For example, in an embodiment where the digital inputs and outputs comprise-bit values, the shared time reference 570 may comprise delay units 571. In such a configuration, signals derived from nodes associated with respective delay units 571 define discrete timing positions (i.e., temporal quantization levels) utilized for time-domain encoding and digitization. In an illustrative-bit embodiment, the shared time reference 570 may comprise sixteen (16) delay units 571 providing sixteen (16) corresponding timing positions.

The delay units 571 may be implemented via various timing generation architectures, including but not limited to counters, tapped delay lines, ring oscillators, or other suitable timing reference generation circuits. By utilizing a common shared time reference 570 for both input pulse generation and output pulse measurement, temporal variations within the timing reference (e.g., jitter or PVT-induced drift) influence both operations in a substantially similar manner. Consequently, the time-domain encoding of the inputs and the digitization of the resultant MAC outputs track a common timing basis across the MAC array, facilitating a self-tracking operational mode that provides first-order cancellation of timing-related errors.

The structural and operational details of the plurality of DTC circuits 510—utilized for generating the input time-domain pulse signals—as well as the constituent components of the TDC circuitry 520 (e.g., the comparator circuitry 550 and the TDC 530) are described in further detail with respect to the following figures. Specifically, the conversion of digital input values into temporal durations and the subsequent quantization of timing events derived from the accumulated signal into digital output values are expanded upon in the context of FIGS. 6A-6C and FIGS. 7A-7C, respectively.

The following descriptions of these discrete conversion and comparison circuitries are intended to illustrate exemplary embodiments and should not be construed as limiting the broader architectural principles of the shared-reference time-domain processing system—disclosed herein.

FIG. 6A illustrates a detailed schematic of an input-side digital-to-time conversion (DTC) structure, in accordance with the architecture previously described with respect to FIG. 5. More particularly, FIG. 6A depicts a circuit path extending from a digital input to a time-domain pulse output configured to drive a row of a multiply-and-accumulate (MAC) array.

For purposes of clarity, FIG. 6A illustrates a single digital input (D1) and a corresponding digital-to-time converter (DTC) 610. However, it is understood that an identical or substantially similar configuration may be provided for each of a plurality of digital inputs (D1 through Dn). The digital input is provided to the DTC 610 and may comprise various bit resolutions (e.g., 2-bit, 4-bit, 8-bit, 16-bit, or other multi-bit values) depending on specific implementation requirements.

The digital-to-time converter (DTC) 610 is operatively coupled to, and configured to operate based on, a common time reference 670. In various embodiments, the common time reference 670 comprises a plurality of delay units 671 arranged to define a timing sequence.

Specifically, the common time reference 670 is configured to receive a trigger signal indicative of a temporal starting point for said timing sequence. In response to the trigger signal, a pulse or signal propagates through the plurality of delay units 671 to generate a sequence of time-staggered signals. These time-staggered signals provide a plurality of distinct phase or timing references for use by the DTC 610 in generating time-domain outputs.

In an exemplary embodiment using a N-bit representation (e.g., a 4-bit representation), the common time reference 670 comprises a plurality of delay units 671 (or delay stages) arranged in a serial configuration.

A plurality of nodes (e.g., taps) associated with respective delay stages are configured to define a set of selectable timing positions (or phase offsets). In the illustrated 4-bit embodiment, the common time reference 670 comprises sixteen (16) delay units 671 operatively coupled in series to provide a corresponding plurality of discrete timing references. However, it will be understood by those skilled in the art that the number of delay units may be scaled (e.g., 2^{N}) to accommodate different bit-depth resolutions without departing from the scope of the present disclosure.

Signals corresponding to discrete delay intervals are extracted from taps or nodes between adjacent delay units 671 and are provided to the input terminals of a multiplexer (MUX) 611 within the DTC 610. Each of these signals represents a distinct temporal phase generated by the common time reference 670. The digital input is coupled to the control or select input of the MUX 611. Responsive to the digital value of D1, the MUX 611 selects a specific timing signal derived from a delay chain consisting of a plurality of delay units 671 connected in series. Consequently, the output of the MUX 611 constitutes a pulse (e.g., “D1 Pulse”) having a temporal duration corresponding to the digital value of D1. This generated pulse signal is subsequently provided to a corresponding row input of the MAC array 590 for time-domain multiply-and-accumulate operations as described in the context of FIG. 5.

As further illustrated in FIG. 6A, signal lines extending from the delay nodes toward the MUX 611 may continue beyond the illustrated connections (indicated by dashed lines). These extensions signify that the same timing signals derived from the common time reference 670 are distributed to a plurality of additional circuits, including output-side digitization circuitry such as time-to-digital converters (TDCs).

By distributing the same timing signals to both the input-generation and output-measurement paths, the system ensures that input encoding and output digitization operate on a common timing basis. This shared-reference architecture facilitates the self-tracking behavior previously described with respect to FIGS. 4 and 5, allowing the input-side time encoding to track variations in the same reference utilized by the output digitization circuitry.

The illustrated-bit resolution and sixteen (16) delay units 671 are provided for exemplary purposes. The disclosed structure is applicable to various digital resolutions, and the number of delay units 671 and selectable timing positions may be scaled accordingly without departing from the scope of the present disclosure.

FIG. 6B illustrates an exemplary operational state of the digital-to-time conversion (DTC) structure described with respect to FIG. 6A, utilizing a specific digital input value for illustrative purposes. In this embodiment, the digital input is a 4-bit value capable of representing sixteen (16) discrete states (e.g., decimal values 0 through 15).

In the illustrated example, the digital input corresponds to a decimal value of 5, represented by the binary vector D1[3:0]=0101. These digital input bits are coupled as control signals (e.g., select signals) to the multiplexer (MUX) 611 within the DTC 610.

As established in FIG. 6A, the common time reference 670 comprises a plurality of delay units 671 coupled in series. For the 4-bit embodiment, sixteen (16) delay units 671 are provided, defining sixteen (16) selectable timing positions (e.g., temporal taps) corresponding to the possible range of the digital input. Each node situated between adjacent delay units 671 provides a timing signal characterized by a distinct accumulated propagation delay. These timing signals are provided as inputs to the MUX 611.

Responsive to the digital value of D1 (decimal 5), the MUX 611 is configured to select the timing signal corresponding to said input value. Because the timing positions are indexed starting from a zero-reference (to), a decimal value of 5 corresponds to the selection of a signal from a node following the sixth delay unit 671 in the delay chain (i.e., the sixth temporal tap).

The selected timing signal is output from the MUX 611 as the time-domain pulse signal “D1 Pulse.” Consequently, the resultant pulse possesses a temporal duration substantially proportional to the delay accumulated through the first six delay units 671 of the common time reference 670. The generated “D1 Pulse” is then provided to a first row of the MAC array 590 associated with input D1, where said pulse facilitates the time-domain multiply-and-accumulate operations previously described.

FIG. 6C illustrates a further exemplary operational state of the digital-to-time conversion (DTC) structure, utilizing a different digital input value to demonstrate full-scale operation. Consistent with the embodiments of FIG. 6B, the digital input D1 is a 4-bit value representing a range of sixteen (16) discrete states. In this instance, the digital input D1 corresponds to a maximum value of the 4-bit representation (i.e., decimal or binary D1[3:0]=1111).

As previously disclosed, the common time reference 670 comprises a serial chain of delay units 671 defining a plurality of selectable timing positions. Each node between adjacent delay units 671 provides a timing signal corresponding to a different accumulated delay. These timing signals are provided as inputs to the multiplexer 611 of the DTC 610. For the illustrated 4-bit embodiment, sixteen (16) delay units 671 generate sixteen (16) corresponding timing signals, each extracted from a distinct node (tap) along the delay chain.

Responsive to the digital input D1 being set to decimal 15, the multiplexer (MUX) 611 is configured to select the timing signal corresponding to the terminal timing position of the delay chain. Specifically, the signal extracted from the node following the sixteenth delay unit 671 is selected and output as the pulse signal “D1.” In this operational state, the generated pulse represents the maximum available pulse duration (full-scale duration) provided by the common time reference 670. The pulse is then provided to the first row of the MAC array 590 to facilitate the time-domain multiply-and-accumulate operations.

The embodiments described with respect to FIGS. 6A-6C demonstrate the mechanism by which digital input values are converted into corresponding time-domain pulse signals via the DTC and the shared common time reference. In accordance with this conversion mechanism, the magnitude of a respective digital input is operatively mapped to a temporal duration (e.g., a pulse width or a time-delay interval).

The digital-to-time converter (DTC) structure described here is designed to work with various types of multiply-accumulate (MAC) systems. Because the DTC converts digital values into timed pulses at the input stage, it is used in different hardware setups, including pulse-based system where the final result on a column is a time pulse (for example, the system shown in FIG. 4), and accumulation-based system where the final result is an analog amount, such as electrical charge or current that builds up along a wire or bitline (for example, the system shown in FIG. 5).

When these pulses are sent into the MAC array 590 at the same time (in parallel), each column in the array creates a resultant signal. This signal represents the final math result in the time domain. Depending on the specific design, this result can take a few different forms. In some embodiments, this result may be a calculated pulse where the timing or width carries the information. Alternatively, the result may be a physical electrical quantity, such as voltage or charge, that accumulated along a column's bitline. The resultant signal is subsequently provided to the output-side digitization circuitry for conversion into a corresponding digital value.

FIG. 7A is a schematic diagram illustrating an exemplary architecture for an output-side time-to-digital conversion (TDC) circuit configured to convert an analog calculated signal into a digital output value. In this embodiment, the calculated signal provided by the MAC array as an analog quantity (e.g., a voltage level or accumulated charge on a column bitline) rather than a time-domain pulse signal.

### Generation of Computational Results: First Configuration (Conf.1)

As illustrated in FIGS. 4 and 5, the claimed device is configured to apply time-domain input pulses (e.g., D1 Pulse through DN Pulse) to the rows of the MAC array. These input pulses interact with weights stored within respective memory cells of the MAC array. For each column of the MAC array, weighted contributions from the plurality of rows are aggregated along a corresponding column bitline to generate a calculated signal (e.g., Calc. Signal 380), which represents a multiply-and-accumulate (MAC) result for said column.

For purposes of the present disclosure, a TDC circuitry 720 configured to process Calc. Signal 1 for a single column is described with reference to FIG. 7A. While FIG. 7A illustrates the circuitry in the context of a single column, it is understood that an identical or substantially similar TDC circuitry 720 may be provided for, and operatively coupled to, each respective column within the MAC array to enable parallel computational processing

As illustrated, the Calc. Signal 1 is provided to a TDC circuitry 720, which comprises comparator circuitry 750 and a time-to-digital conversion converter 730. Within the comparator circuitry 750, the Calc. Signal 1 charges a capacitor (C) 757. In response to the closing of a switching element(S) 755, the capacitive element 757 is configured to discharge through a current source 753 at a substantially constant rate. A comparator 751 is configured to compare the voltage across the capacitive element (Vc) with a reference voltage (Vref).

### Discharge and Timing Sequence

The comparator 751 is configured to maintain a first logic level (e.g., a logic LOW or GND) while Vc exceeds Vref. As soon as the capacitor voltage Vc reaches or drops below Vref, the output of the comparator transitions from the first logic level to a second logic level (e.g., a logic HIGH, or VDD). This flip creates a Comparator Output Pulse (“Comp. Pulse”).

### Temporal Sampling Via Delay Chain

In an illustrated 4-bit embodiment, the TDC 730 includes sixteen flip-flops 733 corresponding to the sixteen timing positions. Each flip-flop 733 is configured to receive the Comp. Pulse and a timing reference signal derived from a common time reference 770.

When the Comp. Pulse is sent to a plurality of flip-flops 733 (sampling elements), the common time reference 770 sends a “start” signal through a delay chain (a series of delay units 771). The common time reference 770 is configured to receive a trigger signal to initiate a timing sequence through a plurality of delay units 771. Consequently, each flip-flop 733 is configured to sample the comparator output pulse at a distinct timing position defined by the delay chain defined by the plurality of delay units 771.

This delay chain acts like a high-speed stopwatch with 16 different “lap” markers. Each flip-flop captures the state of the Comparator Pulse at a slightly different time:

Upon the transition of the comparator output to the second logic level:
Flip-flops 733 associated with earlier timing positions (“Earlier flip-flops” before the transition of the Comp. Pulse) will capture a first logic state (e.g., “0”).
Flip-flops 733 associated with timing positions subsequent to the transition (“Later flip-flops” after the transition of the Comp. Pulse) will capture a second logic state (e.g., “1”).

The resulting output s of the flip-flops 733 constitute a thermometer-coded representation of the timing position of the Comp. Pulse. In other words, the “0s” and “1s” from the flip-flops create a thermometer code (a string of bits that shows exactly where the transition happened). These outputs are provided to an encoder 731 (e.g., a thermometer-to-binary encoder or priority encoder) configured to detect the transition position and generate a digital output value. The encoder 731 may include a thermometer-to-binary encoder, a priority encoder, or other digital logic configured to determine a transition position in the flip-flop outputs and convert the detected position into a digital output value.

In this manner, the TDC circuitry 720 converts the timing of the comparator output pulse, generated in response to the calculated signal, into a multi-bit digital value (e.g., Q1[3:0]) representing the computational result of the corresponding column. In other words, because the input and output resolution is four bits, the encoder generates a 4-bit digital output value (e.g., Q1[3:0]) corresponding to the timing position of the comparator pulse.

### Generation of Computational Results: Second Configuration (Conf.2)

In one or more embodiments, the present disclosure provides the MAC element 390 configured to generate a calculation result in the form of a time-domain pulse, characterized herein as a calculation pulse (Calc. Pulse) 360. Referring to FIGS. 3 and 4, the structural and operational architectures utilized to generate the Calc. Pulse 360 or a plurality of Calc. Pulses are implemented via the circuit configurations and methodologies disclosed in U.S. Pat. No. 12,373,169 which is assigned to ANAFLASH Inc., the disclosure of which is hereby incorporated by reference in its entirety for all purposes.

The present disclosure distinguishes between a first configuration (Conf. 1) and a second configuration (Conf. 2). While Conf. 1 defines a signal path utilizing a comparator 751 to generate a Comp. Pulse, Conf. 2 defines an alternative signal path configured to utilize the Calc. Pulse 360 directly. In Conf. 2, the signal path is configured to bypass the comparator circuitry 750, such that the Calc. Pulse 360 is delivered to the TDC 730 without an intervening comparison operation.

Specifically, in Conf. 2, calculation results are output from the memory array 490 as Calc. Pulse 360, said pulses are configured to bypass the comparator circuitry and are routed directly to the Time-to-Digital Converter (TDC) 730. Specifically, the calculation pulse (Calc. Pulse) 360 is delivered to an input of each flip-flop (FF) 733 in place of a comparison pulse (Comp. Pulse). The inputs for each FF 733 thus comprise a single Calc. Pulse 360 and a single time signal received from the shared time reference 770.

### Inverted Transition Logic

Although the physical input terminals for both configurations may be substantially identical or structurally analogous, the transition detection logic of Conf. 2 is inverted relative to that of Conf. 1:

In Conf. 1, a comparison pulse (Comp. Pulse) initiates in a Low state and transitions to a High state (rising edge) at a detection point defined by the comparator threshold.

In Conf.2, the initiation of a calculation pulse (Calc. Pulse) 360 is synchronized with a trigger signal of a time reference 770, which serves as a temporal origin. Due to said synchronization, the Calc. Pulse 360 initiates in a High state.

The Calc. Pulse 360 remains in said High state for a duration corresponding to the calculation result and undergoes a transition to a Low state (falling edge) at the conclusion of said duration. In this embodiment, the FF 733 is configured to detect this Low-going transition. Upon detection of said falling edge, the FF 733 provides a corresponding signal to the encoder 731 for digital conversion.

FIG. 7B is a timing diagram and operational flow of a conversion process performed by the output-side time-to-digital conversion (TDC) circuitry according to one embodiment.

In the illustrated embodiment, a calculated signal (e.g., “Calc. Signal 1”) is generated by the array and provided to the comparator circuitry 750 of the TDC circuitry 720. The calculated signal is configured to charge a capacitive element (C) 757. In this embodiment, the calculated signal provided from the array is represented as an analog quantity, such as a voltage or accumulated charge on a column bitline, rather than a time-domain pulse.

Upon the transition of the switching element(S) 755 to a closed state, the capacitive element 757 is discharged via a current source 753. In a preferred embodiment, the current source 753 provides a substantially constant current, such that the voltage across the capacitive element (Vc) decreases according to a substantially linear decay over time, as depicted in the voltage waveform 752.

The comparator 751 is configured to perform a continuous or periodic comparison between capacitor voltage Vc with a reference voltage Vref.

As shown in the output waveform 754, the output of the comparator 751 is maintained at a first logic level (e.g., a “low” level) while Vc remains above Vref. At a specific temporal instant (Tp) where Vc reaches or crosses Vref, the comparator 751 is configured to transition its output to a second logic level (e.g., a “high” level), thereby generating a comparator output pulse.

As previously noted, two example waveforms 752 and 754 show the relationship between the capacitor voltage Vc and time, and the corresponding comparator output pulse. The first waveform 752 shows the decrease of Vc over time and the determination of the time Tp at which Vc becomes equal to Vref. The second waveform 754 illustrates the corresponding transition of the comparator output from a low level to a high level at the time Tp.

The comparator output pulse is distributed to a plurality of flip-flops 733 (sampling elements) within the TDC 730. In the illustrated 4-bit exemplary architecture, sixteen sampling elements 733 are provided, each corresponding to one of sixteen discrete timing positions derived from the common time reference 770.

Each flip-flop 733 is configured to receive: (1) the comparator output pulse as a data input; and (2) a timing signal (e.g., a clock or strobe) corresponding to a unique delay stage of the common time reference 770.

Consequently, each sampling element 733 captures the state of the comparator output at a distinct, time-staggered interval. As shown in FIG. 7B, the timing positions and sampling element outputs associated with the first logic state are represented by a first visual indicator (e.g., thin gray lines), while those associated with the second logic state—occurring at or after the transition—are represented by a second visual indicator (e.g., thicker black lines).

In an exemplary operational state where the comparator output transitions at a time coincident with a seventh delay unit 771:
Sampling elements associated with timing positions prior to the transition capture a first logic value (e.g., “0”).
Sampling elements associated with timing positions at or subsequent to the transition capture a second logic value (e.g., “1”).

The collective outputs of the sampling elements 733 thereby constitute a thermometer-coded representation of the temporal position of the comparator transition.

The thermometer-coded outputs are supplied to an encoder 731. The encoder 731 comprises logic configured to identify the transition boundary (e.g., the “0-to-1” transition) within the sampling element outputs and map said boundary to a multi-bit digital value. In the present example, where the transition is detected at the seventh timing position (indexed as position six in a zero-based index), the encoder 731 generates a 4-bit digital output value (e.g., binary 0110). Through this sequence, the timing of the comparator output pulse—generated in response to the calculated signal—is digitized into a numerical value representing the magnitude of the computation result.

FIG. 7C is a timing diagram illustrating another operational state of the output-side TDC structure. Specifically, FIG. 7C depicts the conversion of a calculated signal having a greater magnitude than the magnitude illustrated in FIG. 7B.

In this embodiment, the MAC array generates a second calculated signal (“Calc. Signal 2”) and provides it to the comparator circuitry 750. The magnitude of this calculated signal corresponds to the quantity of electrical charge stored on the capacitive element 757. As illustrated in the first waveform 752, the initial voltage level across the capacitive element 757 is higher than the initial voltage level shown in the FIG. 7B. Because Calc. Signal 2 has a higher magnitude than Calc. Signal 1 of FIG. 7B, a greater charge is stored on the capacitor C 757, resulting in a higher initial potential across the capacitor relative to the state in FIG. 7B.

Upon the closing of the switching element S 755, the capacitor 757 begins to discharge through the current source 753. Because the current source 753 is configured to provide a substantially constant current, the capacitor voltage Vc decreases at a substantially linear rate over time. The comparator 751 continuously compares the capacitor voltage Vc with the reference voltage Vref. Due to the increased magnitude of Calc. Signal 2, the initial voltage stored on capacitor C 757 is elevated, thereby requiring a longer discharge interval for Vc to reach to the threshold of Vref than the discharge interval of FIG. 7B.

As depicted in the second waveform 754, the temporal instant (Tp) at which the comparator 751 transitions to a second logic state is delayed relative to the transition timing in FIG. 7B. The comparator output remains at a first logic state (e.g., a logic LOW) for an interval corresponding to the discharge period and transitions to the second logic state (e.g., a logic HIGH) only when the capacitor voltage Vc reaches or crosses the reference voltage (Vref). Because the starting voltage of FIG. 7C was higher than the starting voltage of FIG. 7B, it takes longer to reach that point (the reference voltage), which create a comparator output pulse (Comp. Pulse) with a delayed or “shifted” leading edge.

The comparator output pulse is supplied to the plurality of flip-flops 733 within the time-to-digital converter (TDC 730). Consistent with the previously described 4-bit architecture, each sampling element 733 captures the state of the comparator output pulse at a discrete timing position derived from the common time reference 770.

In the illustrated operational scenario:
The comparator transition is coincident with the fifteenth timing position (or fifteenth delay unit 771).
Flip-flops (sampling elements) associated with timing positions one through fourteen capture a first logic value (e.g., “0”).
Flip-flops (sampling elements) associated with the fifteenth timing position and any subsequent positions capture a second logic value (e.g., “1”).

The collective outputs of the sampling elements 733 thus form a thermometer-coded representation indicative of the temporal position of the comparator transition.

The thermometer-coded outputs are supplied to an encoder 731. The encoder 731 comprises logic configured to detect a transition boundary (e.g., a “0-to-1” transition) and map said boundary to a multi-bit digital value.

In the present example, where the transition is detected at the fifteenth timing position (indexed as position fourteen in a zero-based index), the encoder 731 generates a 4-bit digital output value (e.g., binary 1110). Through this sequence, the timing of the comparator output pulse is digitized into a numerical value commensurate with the magnitude of the computation result.

Through this operation, a larger calculated signal corresponds to a larger digital output value, thereby representing a larger computation result produced by the array.

What is claimed is:

1. A memory device for performing time-domain multiply-and-accumulate (MAC) computations, the memory device comprising:
a memory array comprising a plurality of memory cells;
a first circuit comprising a plurality of digital-to-time converters (DTC);
a second circuit comprising a plurality of time-to-digital converters (TDC); and
a time reference circuit operatively coupled to the plurality of DTCs and the plurality of TDCs, wherein the time reference circuit is configured to synchronously generate and distribute a set of time-staggered signals to the plurality of DTCs and the plurality of TDCs.

2. The memory device of claim 1, wherein the memory array is configured to:
perform a plurality of the multiply-accumulate (MAC) operations; and
output, via a corresponding bit line, an intermediate signa representing a sum of products of the MAC operations, wherein the intermediate signal comprises one of:
a time-domain pulse signal having a pulse width corresponding to the sum of products, and
an accumulated analog signal comprising at least one of an accumulated current or an accumulated voltage.

3. The memory device of claim 2, wherein each DTC is configured to transform a digital input signal into a time-domain output pulse, wherein a duration or a phase offset of the time domain output pulse corresponds to a magnitude of the digital input signal.

4. The memory device of claim 3, wherein each DTC comprises:
a plurality of time-staggered input ports configured to receive a plurality of time-staggered versions of a reference pulse via a plurality of delay lines coupled to the time reference circuit;
one or more digital input ports configured to receive a multi-bit digital code;
a multiplexer configured to select one of the plurality of time-staggered versions of the reference pulse based on the multi-bit digital code; and
a common output port configured to provide the selected time-staggered version of the reference pulse.

5. The memory device of claim 4, wherein the digital input ports are configured to receive an n-bit signal, and the multiplexer is configured to select one of 2ⁿ distinct temporal phases derived from the time reference circuit.

6. The memory device of claim 1, wherein the plurality of DTCs are disposed along rows of the memory array, and wherein a total number of DTCs is based on a number of the rows in the memory array.

7. The memory device of claim 1, wherein the time reference circuit comprises:
an input node configured to receive a reference trigger signal;
a delay line comprising a plurality of unit delay cells arranged in series, each unit delay cell configured to impart a predetermined temporal delay to the reference trigger signal; and
a plurality of output taps, each output tap coupled to a node between adjacent unit delay cells to provide the set of time-staggered signals.

8. The memory device of claim 2, wherein each TDC is coupled to a corresponding column of the memory array.

9. The memory device of claim 8, wherein each TDC is configured to:
receive the time-domain pulse signal from the plurality of memory cells via the corresponding column of the memory array, the time-domain pulse signal having a pulse width or a temporal edge position representing the sum of products of the MAC operations; and
quantize the time-domain pulse signal to generate a multi-bit digital output signal by comparing a temporal characteristic of the time-domain pulse signal against at least one of the time-staggered signals distributed by the time reference circuit.

10. The memory device of claim 8, wherein each TDC comprises:
a comparator unit comprising at least one comparator, the comparator unit configured to generate a common pulse signal based on a comparison of the accumulated analog signal against a reference threshold;
a sampling unit comprising a plurality of sampling elements, each sampling element having a data input coupled to an output of the comparator and a clock input coupled to one of the time-staggered signals distributed by the time reference circuit, the plurality of sampling elements configured to sample the common pulse signal to generate a thermometer-coded output representing a temporal characteristic of the common pulse signal; and
an encoder operatively coupled to the plurality of sampling elements, the encoder configured to convert the thermometer code output into a multi-bit digital output.

11. The memory device of claim 10, wherein the comparator unit comprises at least one capacitive element operatively coupled to a column of the memory array, wherein the capacitive element is configured to:
accumulate a charge representing an accumulated contribution of signals generated by the memory cells; and
transduce said accumulated charge into a voltage value at an input of the at least one comparator.

12. The memory device of claim 11, wherein the comparator is coupled to the capacitive element, said comparator is configured to:
sense a voltage level developed across the capacitive element, the voltage level being proportional to the result of a MAC operation; and
generate a common pulse signal in response to the sensed voltage level reaching a reference voltage threshold.

13. The memory device of claim 12, wherein the at least one comparator is further configured to distribute the common pulse to the plurality of sampling elements.

14. The memory device of claim 13, wherein the common pulse signal is configured to trigger sampling of the common pulse signal across the plurality of sampling elements.

15. The memory device of claim 10, wherein each sampling element comprises:
a first input terminal configured to receive one of the set of time-staggered signals from the time reference circuit; and
a second input terminal configured to receive the common pulse from the comparator, wherein a time of the common pulse corresponds to a magnitude of the MAC results.

16. The memory device of claim 10, wherein each sampling element is configured to receive a respective time-delayed version of a reference signal to define a plurality of discrete sampling windows; and wherein each sampling element is configured to latch a logical state of the common pulse signal at a unique sampling time.

17. The memory device of claim 11, wherein the encoder comprises:
an input interface configured to receive parallel signals from the plurality of sampling elements;
a transition detection circuitry configured to identify a transition bit position between a first logic state and a second logic state; and
an encoding logic circuitry configured to convert the identified transition bit position into a n-bit binary number.

18. The memory device of claim 17, wherein the n-bit digital representation corresponds to a quantized timing position of a common pulse signal relative to a reference signal.

19. A method for performing time-domain multiply-and-accumulate (MAC) operations in a memory device, the method comprising:
generating and distributing, by a time reference circuit, a set of time-staggered signals to a plurality of digital-to-time converters (DTC) and a plurality of time-to-digital converters (TDC);
transforming, by the plurality of DTCs, a plurality of digital input signals into time-domain pulses, wherein a temporal characteristic of each time-domain pulse is determined by selecting one of the time-staggered signals based on a multi-bit digital code;
performing, via a memory array, a plurality of MAC operations by applying the time-domain pulses to a plurality of memory cells;
generating, via the memory array, a plurality of intermediate signals, wherein each intermediate signal represents a sum of products of the MAC operations; and wherein each intermediate signal comprises one of a time-domain pulse signal and an accumulated analog signal; and
quantizing, by the plurality of TDCs, the intermediate signal to generate a multi-bit digital output signal by comparing a temporal characteristic of the intermediate signal against at least one of the time-staggered signals provided by the time reference circuit, wherein the multi-bit digital output represents a sum of respective products generated by the plurality of circuits.

20. A system for performing time-domain multiply-and-accumulate (MAC) operations in a memory device, the system comprising:
a time reference circuit configured to generate a plurality of time-staggered reference signals;
a plurality of digital-to-time converters (DTC), each configured to receive a digital input and select one of the time-staggered reference signals received from the time reference circuit to generate a time-domain input pulse signal;
a memory array comprising a plurality of memory cells arranged in rows and columns, the memory cells configured to perform multiply-and-accumulate (MAC) operations using the time-domain input pulse signals and to output an intermediate signal; and
a plurality of time-to-digital converters (TDC), each coupled to a column of the memory array and the time reference circuit, the plurality of TDCs configured to:
sample the intermediate signal against the plurality of time-staggered reference signals to identify a temporal transition; and
encode the temporal transition into a digitized value representing a sum of respective products generated by the plurality of memory cells.
